(19) United States
(12) Patent Application Publication
(10) Pub. No.: US 2026/0341351 A1
(43) Pub. Date: Oct. 29, 2026

(54) RESISTOR STRUCTURE, CONVERTER, METHOD OF OPERATING A RESISTOR STRUCTURE AND METHOD OF OPERATING A CONVERTER

(71) Applicant: Infineon Technologies AG, Neubiberg (DE)

(72) Inventors: Irene Munoz Martin, Villach (AT); Stefano Bianchi, Villach (AT)

(21) Appl. No.: 19/648,770

(22) Filed: Apr. 15, 2026

(30) Foreign Application Priority Data
Apr. 23, 2025 (DE) 102025115582.8

(51) Int. Cl. G11C 13/00; G11C 11/16; G11C 11/22; H01C 1/16; H03M 1/66

(52) U.S. Cl. CPC G11C 13/0028; G11C 13/003; H01C 1/16; H03M 1/66; G11C 11/16; G11C 11/22; G11C 13/0004; G11C 2213/79

(57) ABSTRACT

In accordance with an embodiment, a resistor structure includes a plurality of resistor elements, including a first set of resistor elements of the plurality of resistor elements, where each resistor element of the first set of resistor elements is connected in parallel between a first bitline and a first sourceline; and at least one further set of resistor elements of the plurality of resistor elements, where each resistor element of the at least one further set of resistor elements is connected in parallel between a respective further bitline and a respective further sourceline; and at least one switch configured to switch the resistor structure between a first state and a second state.

### CROSS-REFERENCE TO RELATED APPLICATIONS

This application claims the benefit of German Patent Application No. 102025115582.8, filed on Apr. 23, 2025, which application is hereby incorporated herein by reference.

### TECHNICAL FIELD

Various embodiments relate generally to a resistor structure, a converter, a method of operating a resistor structure, and to a method of operating a converter.

### BACKGROUND

Various electronic devices like digital-to-analog converters (DACs), sensors, clock generation circuits, etc., may require a linear voltage sweep to be provided in integrated circuits.

Conventional devices may for example use capacitors for providing the linear voltage sweep, which may have a high area- and energy consumption.

### SUMMARY

A resistor structure is provided. The resistor structure includes a plurality of resistor elements, including a first set of resistor elements of the plurality of resistor elements, wherein each resistor element of the first set of resistor elements is connected in parallel between a first bitline and a first sourceline, and at least one further set of resistor elements of the plurality of resistor elements, wherein each resistor element of the at least one further set of resistor elements is connected in parallel between a respective further bitline and a respective further sourceline, and at least one switch configured to switch the resistor structure between a first state and a second state, wherein, in the first state, each resistor element of the plurality of resistor elements is programmable into one of a plurality of predefined resistive states, and, in the second state, the first sourceline is connected to the further bitline of the at least one further set of resistor elements.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic illustration of a resistor structure in accordance with various embodiments;

FIG. 2 shows a schematic illustration of a resistor structure in accordance with various embodiments;

FIG. 3 illustrates output voltages of a resistor structure in accordance with various embodiments in sweeps of increasing resistance for various temperatures;

FIG. 4 shows a schematic illustration of a converter in accordance with various embodiments; and

FIG. 5 shows a flow diagram of a method of operating a resistor structure in accordance with various embodiments.

### DETAILED DESCRIPTION OF ILLUSTRATIVE EMBODIMENTS

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

Devices described herein include pluralities of similar or identical structures (e.g., a plurality of resistor elements, pluralities of sourcelines, bitlines, wordlines, switches, etc.). To avoid crowding, only a few of these structures are labelled in the figures, where the skilled person may easily identify the corresponding similar/identical structures. Furthermore, to differentiate between individual elements, sets or groups among the plurality, a common reference sign is provided with trailing individual identifiers. It is to be understood that the common reference sign is used for the plurality, e.g., SL may be used in the description for the plurality of sourcelines, even though the Figures may possibly only identify individual sourcelines SL_1, SL_F1, SL_FN, and vice versa.

Recent breakthroughs in the field of non-volatile memories, such as RRAMs and PCRAMs, have introduced a possibility of having low-area arrays of programmable resistive devices.

Various embodiments provide precise linear voltage sweeps in integrated circuits that enable low-power digital to analog conversion and improve data converters, thus overcoming current technological limitations and paving the way for feasible “beyond CMOS” computation.

Various embodiments provide a method for driving a resistor structure, for example a memristive array, for enabling multi-bit thermometric linear voltage sweeps in integrated circuits. The resistor structure and the corresponding method provide a low-power and low-area basic building block that is applicable for boosting low-power analog design (e.g. for data converters, sensors, data management, clock generation).

Resistor structures of various embodiments, for example of non-volatile memories (NVMs) such as Resistive Random Access Memories (RRAMs) or Phase Change Random Access Memories (PCRAMs), may use resistive elements, for example memristors, that have the possibility of being switched between at least two different resistive levels by applying proper electrical writing signals.

Memristors may thus be considered not only as memory elements, but also as programmable resistors that may be built in the back-end-of-the-line in accordance with a crossbar architecture.

Furthermore, each device may be built in accordance with a pitch corresponding to the present technology.

Memristors, which may be part of a resistor structure in accordance with various embodiments, may be read in parallel for achieving a one-shot linear output signal as a function of an input voltage array.

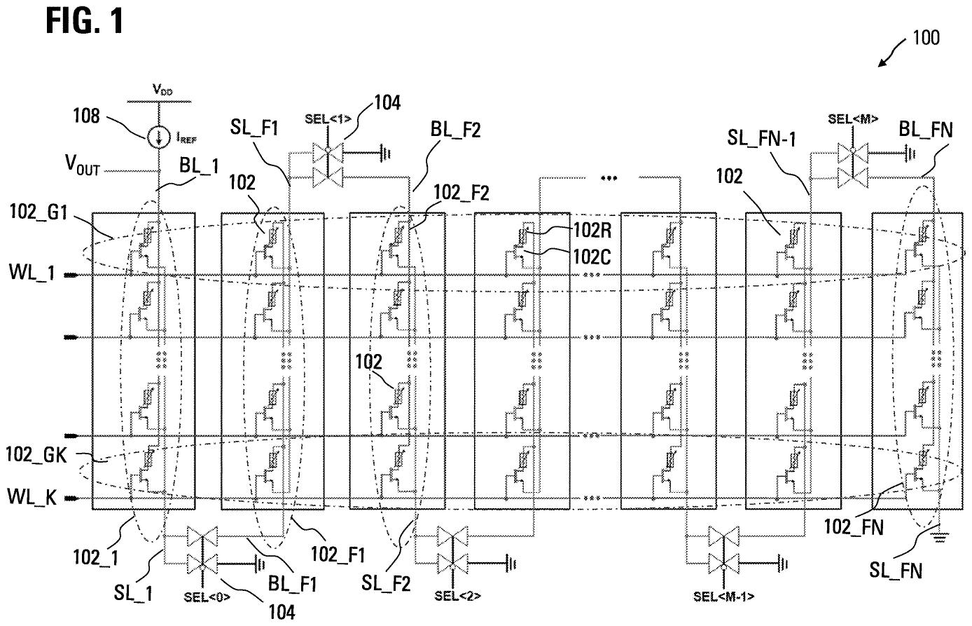

FIG. 1 shows a schematic illustration of a resistor structure 100 in accordance with various embodiments.

The resistor structure 100 includes a plurality of resistor elements 102.

The resistor structure 100 may be configured in a similar way as a non-volatile memory (NVM) that is based on a plurality, e.g., an array, of individually addressable memory elements that are configured to store data values by being switched between multiple resistive states. The array of resistor elements 102 may include rows of resistor elements 102 arranged along wordlines WL and columns of resistor elements 102 arranged along sourcelines SL and bitlines BL.

Thus, the plurality of resistor elements 102 may be similar to the memory elements of a memory device and may, in a first state of the resistor structure 100, be individually and/or group-wise programmable (a group of resistor elements 102_G1 to 102_GK may include all resistor elements 102 that are connected to a same wordline WL and may optionally be programmed as a group into one of a plurality of predefined resistive states by a combination of activated wordline WL, activated bitline BL and activated SL). A more detailed description in relation to other elements of the resistor structure 100 will be provided later. Some circuit portions that may be used for the programming of the resistor elements 102 and which may be similar or identical to a conventional writing process, but not for the realization of the resistor structure 100 per se, may have been omitted.

Each of the resistor elements 102 may include a resistive structure 102R and a control structure 102C for switching a current through the resistive structure 102R. The control structure 102C may for example include or consist of a transistor, for example a Metal Oxide Semiconductor Field Effect Transistor (MOSFET).

Pluralities of sourcelines SL, bitlines BL, and wordlines WL, respectively, may be provided for individually addressing, e.g., programming, the resistor elements 102 in the first state of the resistor structure 100.

The resistor elements 102 may for example be or include Resistive Random Access Memory (RRAM) elements, Magnetic Random Access Memory (MRAM) elements, Phase-Change Random Access Memory (PCRAM, PRAM or PCM) elements, or Ferroelectric Random Access Memory (FRAM or FeRAM) elements.

The plurality of resistor elements 102 includes a first set of resistor elements 102_1 and at least one further set of resistor elements 102_F1, 102_F2, . . . , 102_FN. The at least one further set of resistor elements 102_F1, 102_F2, . . . , 102_FN may thus for example include just one further set of resistor elements 102_F1, or more than one further set of resistor elements, for example two further sets of resistor elements 102_F1, 102_F2, or for example up to N further sets of resistor elements 102_F1, . . . , 102_FN.

Each resistor element 102 of the first set of resistor elements 102_1 is connected in parallel between a first bitline BL_1 of the plurality of bitlines BL and a first sourceline SL_1 of the plurality of sourcelines SL.

Each resistor element 102 of the at least one further set of resistor elements 102_F1, 102_F2, . . . , 102_FN is connected in parallel between a respective further bitline BL_F1, . . . , BL_FN and a respective further sourceline SL_F1, . . . , SL_FN.

This is to be understood in such a way that each of the at least one further set of resistor elements 102_F1, 102_F2, . . . , 102_FN has, among the plurality of bitlines BL and sourcelines SL, respectively, its own corresponding pair of bitline BL and sourceline SL. For example, the first further set of resistor elements 102_F1 may be connected in parallel between a first further bitline BL_F1 of the plurality of bitlines BL and a first further sourceline SL_F1 of the plurality of sourcelines SL. The second further set of resistor elements 102_F2 may be connected in parallel between a second further bitline BL_F2 of the plurality of bitlines BL and a second further sourceline SL_F2 of the plurality of sourcelines SL, etc., and the N-th further set of resistor elements 102_FN may be connected in parallel between an N-th further bitline BL_FN of the plurality of bitlines BL and an N-th further sourceline SL_FN of the plurality of sourcelines SL.

The resistor structure 100 further includes at least one switch 104 configured to switch the resistor structure 100 between the first state and a second state. The at least one switch 104 may for example include one or more transistors, e.g., MOSFETs, e.g. single NMOS or PMOS pass-device, and/or transmission gate.

Digital signals SEL<0>, . . . , SEL<M> may be provided for switching the at least one switch 104, for example for driving gates of respective transistors.

As described above, in the first state, each resistor element 102 of the plurality of resistor elements 102 is programmable (e.g., individually and/or group-wise; each group 102_G1, . . . , GK of the plurality of groups 102_G may include at least one resistor element 102 from the first set 102_1 of resistor elements and at least one resistor element 102 each from the further sets 102_F1, 102_F2, . . . , 102_FN of resistor elements, wherein each of the resistor elements 102 includes a resistive structure 102R and a control structure 102C for switching a current through the resistive structure 102R, and wherein the control structures 102C of each group 102_G1, . . . , GK of resistor elements are connected in parallel to a wordline WL of a plurality of wordlines WL) into one of the plurality of predefined resistive states.

In various embodiments, as is often the case for NVM devices, the resistor elements 102 may be programmable into two different resistive states, e.g., a low resistive state and a high resistive state. However, more than two resistive states, e.g., three or more resistive states, may be used in various embodiments.

In the second state, the first sourceline SL_1 is connected to the further bitline BL_F1 of the at least one further set of resistor elements 102_F1. In various embodiments, the connection between the first sourceline SL_1 and the further bitline BL_F1 may be a serial connection, which is the exemplary embodiment that is illustrated in FIG. 1. In various embodiments, the connection between the first sourceline SL_1 and the further bitline BL_F1 may be a parallel connection.

In various embodiments, one or more of the respective further sourcelines SL_F1, . . . , SL_FN−1 may be connected, e.g., in series and/or in parallel, with a subsequent respective further bitline BL_F2, . . . , BL_FN.

In FIG. 1, all connections between the sets of resistor elements 102_1, 102_F1, . . . , 102_FN are serial connections. More generally, the connections between the sets of resistor elements 102_1, 102_F1, . . . , 102_FN may be parallel connections, or a combination of parallel and serial connections.

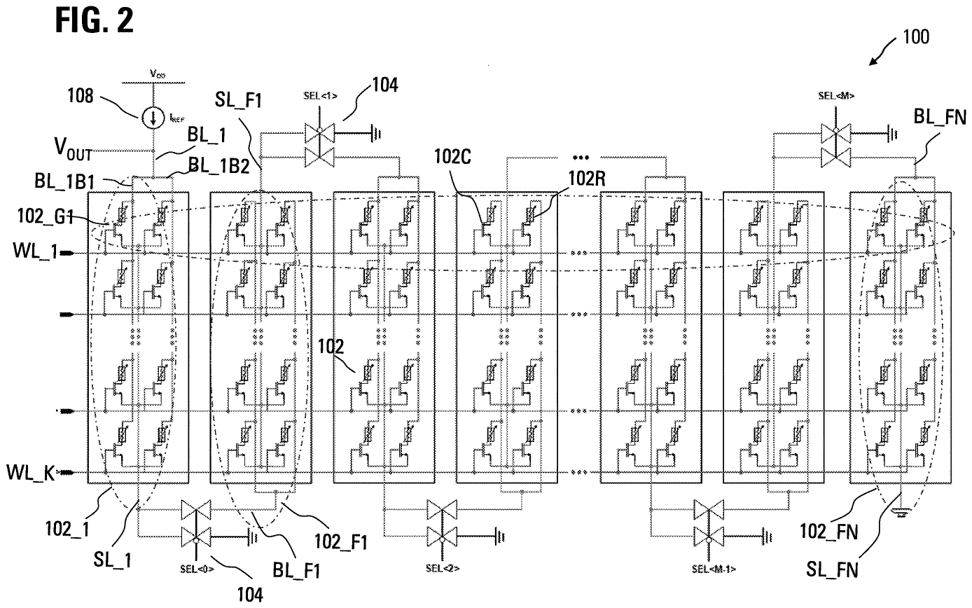

FIG. 2 shows a schematic illustration of a resistor structure 100 in accordance with various embodiments.

The resistor structure 100 of FIG. 2 may in various aspects be similar to the resistor structure 100 of FIG. 1, and duplications of respective features may be omitted for sake of brevity. Please refer to FIG. 1 for a description of such features. The focus may instead be on pointing out differences between the embodiments of FIG. 1 and of FIG. 2.

In the resistor structure 100 of FIG. 2, the first bitline BL_1 includes a plurality of first bitline branches BL_1B1, BL_1B2 that are connected in parallel. Furthermore, each of the further bitlines BL_F1, . . . , BL_FN includes a plurality of further bitline branches BL_F1B1, BL_F1B2, and so forth, that are connected in parallel.

In the exemplary embodiment of FIG. 2, two parallel branches BL_1B1, BL_1B2 are provided for each of the (further) bitlines BL_1, BL_F1, . . . , BL_FN. More generally, more than two parallel branches may be provided for each set of resistor elements 102_1, 102_F1, . . . , 102_FN.

In the exemplary embodiment of FIG. 2, one sourceline SL is provided for each set of resistor elements 102_1, 102_F1, . . . , 102_FN, which means that the resistor elements 102 connected to each of the first bitline branches BL_1B1, BL_1B2 are connected in parallel between the respective bitline branch BL_1B1, BL_1B2 and the (single) sourceline SL_1. This also applies, mutatis mutandis, to the resistor elements 102 of the respective further sets of resistor elements 102_F1, . . . , 102_FN.

In various embodiments, as an alternative to the plurality of branches for the bitlines BL or in addition thereto, the sourcelines SL may be provided as pluralities of branches (not shown). In other words, the first sourceline SL_1 may include a plurality of first sourceline branches that are connected in parallel, and/or each of the further sourcelines SL_F1, . . . , SL_FN may include a plurality of further sourceline branches that are connected in parallel.

A configuration in accordance with the embodiment of the resistor structure 100 described in context with FIG. 2 may have the advantage of sharing the same sourceline SL within each set of resistor elements 102, which may help to keep a layout more compact from an array design point of view.

More generally, still, similar architectures of memory arrays may be used for providing the resistor structure 100 of various embodiments.

Any suitable structure that connects together bitlines and sourcelines to form a series of impedances may be used to form the resistor structure 100 of various embodiments.

The second state may, in any of the embodiments, be used as follows:

In order to provide thermometric precision for output voltages used in integrated circuits, the crossbar architecture of the non-volatile resistive memories, which show good retention (e.g., RRAMs and PCMs), may be used to combine several devices, for example to connect them in series, in parallel, or in a combined pattern of serial and parallel connections.

Each of FIGS. 1 and 2 illustrates an exemplary embodiment of the resistor structure 100, where a current source 108 (e.g., coming from a bandgap- or from a Proportional To Absolute Temperature (PTAT) circuit) is used to feed a crossbar array of resistive elements 102. The current enters, through the first bitline BL_1, into the first set 102_1 of (parallel) resistor elements 102.

In both, the first state and the second state, a number of resistor elements 102 that are connected in parallel in a given set of resistor elements 102_1, . . . , 102_FN may be selected by driving/activating a corresponding number of wordlines WL. The wordlines WL may for example be connected to the control structure 102C of each respective resistor element 102, e.g., to a gate of a transistor, and may for example drive an ohmic state of each control structure 102C, e.g., each MOSFET selector. Since the current is solenoidal, for Kirchhoff s laws, it is then gathered in the first sourceline SL_1 and is sent out from the array.

In the second state, in which the switch 104 is set to activate the second state of the resistor structure 100 (in FIG. 1: SEL<0> is activated), the current flows to the subsequent bitline, e.g., in FIG. 1, to the first further bitline BL_F1.

This conceptual architecture may in various embodiments be replicated also for the following sets of resistor elements 102_F1, 102_F2, . . . , 102_FN, and further sourcelines SL and bitlines BL, respectively, as illustrated in FIG. 1 and/or explained herein.

An output voltage V_{OUT}, in the case all the resistor elements 102 are programmed to the same resistive value, may be measured between an input line connected to the first bitline BL_1 and an output line connected to a last further sourceline SL_FN (which is not connected to a subsequent bitline) is:

$${V}_{OUT} = {I}_{REF} {\sum }_{BL = 0}^{M} \frac{{R}_{RE}}{\# ( WL )} \qquad ( I )$$

wherein I_{REF} is a generic input current of the resistor structure, which in each of FIGS. 1 and 2 is represented by the current source 108, BL is an index of the bitlines that are included in the summation (the resistor structure 100 may include N+1 sets of resistor elements 102_1, 102_F1, . . . , 102_FN, and the resistor elements 102 of each of the sets may typically be connected in parallel to one bitline BL, but the summation may include only those bitlines BL between the lower summation index 0 and the upper summation index M that are actually connected to a preceding sourceline SL), R_{RE} is a resistance of the resistive elements 102 (which is switchable between the plurality of resistive states), and #(WL) is the total number of activated wordlines WL. In the case the resistive elements 102 are programmed differently from one another, the formula can be generalized in the following way:

$${V}_{OUT} = {I}_{REF} {\sum }_{BL = 0}^{M} {R}_{EQ - BL} \qquad ( II )$$

In which R_{EQ-BL} is the equivalent resistance of each 102_1 group of resistive elements. Note that, in this formula, each 102_1 group of resistive elements could have a corresponding different resistive value. For sake of simplicity, in the following we refer to formula “I”.

In other words, the voltage V_{OUT} may be the product of the input current I_{REF} times the summation of the activated bitlines BL (always divided by the activated wordlines WL, since all the wordlines WL are shared across the array).

In other words, the exemplary embodiments of resistor structures 100 shown in FIGS. 1 and 2, respectively, may be representative architectures for achieving linear voltage sweeps as a function of switch states of the switches 104 (the SEL< > signals, either activating or de-activating a connection between subsequent sets of resistor elements 102_1, 102_F1, . . . , 102_FN). The respective switches 104 (e.g., at least one per switchable connection, e.g., between each pair of subsequent sets of resistor elements 102_1, 102_F1, . . . , 102_FN) may be configured to connect bitlines BL and sourcelines SL of the subsequent sets of resistor elements 102_1, 102_F1, . . . , 102_FN one after the other, thus assuring a modular architecture for providing digital to analog conversion of the input selection. In the second state, the first sourceline SL_1 is individually switchable to be connected to the further bitline BL_F1, . . . , BL_FN of the at least one further set 102_F1, . . . , 102_FN of resistor elements. One or more of the respective further sourcelines SL_F1, . . . , SL_FN is individually switchable to be connected to a subsequent respective further bitline BL_F1, . . . , BL_FN. Individual bits of the digital input signal <SELo>, . . . , <SELM> are configured to control switches to either activate or de-activate a connection between the first sourceline SL_1 and the further bitline BL_F1, . . . , BL_FN and between the respective further sourcelines SL_F1, . . . , SL_FN and the subsequent respective further bitline BL_F1, . . . , BL_FN, and thereby between subsequent sets of resistor elements 102_1, 102_F1, . . . , 102_FN.

In various embodiments, I_{REF} may be provided by a PTAT, and may thus compensate a natural resistance drift of the resistor elements 102. In various embodiments, other suitable current sources 108, e.g., a PMOS mirror, may be used.

In various embodiments, the wordlines WL may be driven to add/remove resistor elements 102 in parallel, offering a further degree of freedom for calibration. In other words, the resistor structure 100 may be configured to add, in the second state, to an equivalent resistance of the resistor structure 100, respective resistances of the resistor elements 102 connected to at least one wordline WL of the plurality of wordlines WL by activating the at least one wordline WL, and/or to remove, from the equivalent resistance of the resistor structure 100, respective resistances of the resistor elements 102 connected to the at least one wordline WL by deactivating the at least one wordline WL.

In various embodiments, M may be larger than or equal to two when the resistor structure 100 is in the second state.

The (e.g., combined) states of the switches 104, e.g., the digital signals SEL<0>, . . . , SEL<M>, may determine a total resistance of the resistor structure 100 and thereby the output voltage V_{OUT}. Thus, the resistor structure 100 may be suitable for being used in a converter for converting a digital input signal (the digital signals SEL<0>, . . . , SEL<M>) to an analog output signal (the output voltage V_{OUT}).

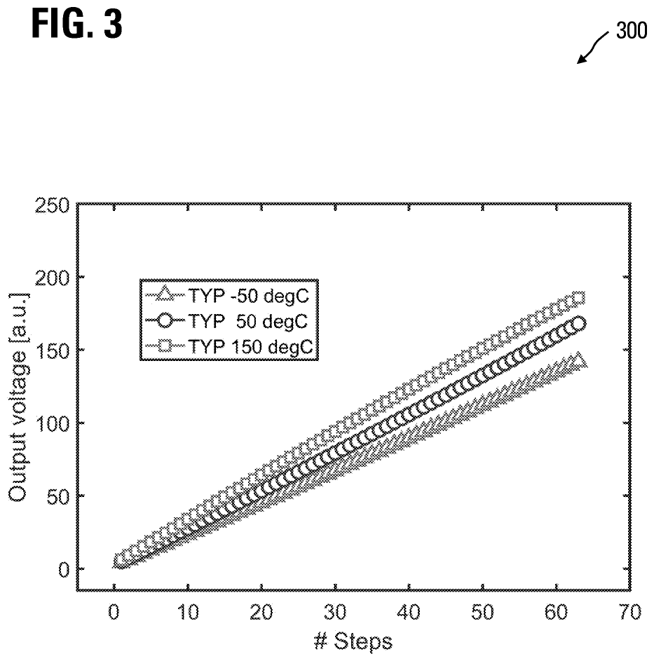

FIG. 3 illustrates this in a graph of output voltages V_{OUT} of a resistor structure 100 in accordance with various embodiments in sweeps of increasing resistance for various temperatures. In the experiment that was conducted to generate the measurements, 6 bit (64) of thermometric levels were provided and all resistor elements 102 were programmed to the same low resistive state. Thus, the resistor structure 100 has a low current and power consumption and is implemented in an area-efficient way.

The sweeps of increasing resistance are to be understood as, in Step #1, activating on only the first switch 104 (SEL<0> in FIG. 1), in Step #2, activating both, the first switch and the second switch 104 (SEL<0> and SEL<1> in FIG. 1), and so forth, up to M=64 (corresponding to 6 bit), where all switches 104 from SEL<0> to SEL<63> are activated.

The output voltages V_{OUT} show excellent linearity. A gain of the linear relationship may vary with temperature. Indicated temperatures span, in an exemplary fashion, a range that may be encountered in an automotive application. The gain variability may be minimized by adjusting a number of simultaneously activated wordlines WL. For example, a calibration procedure may be performed as a function of the temperature variations (usually referred to as PVT variations, for “Process, Voltage, Temperature variations). Additional adjustments may include varying the predefined resistive states of the resistive elements 102.

In summary, the resistive structure 100 of various embodiments was shown to be suitable for achieving multi-bit digital-to-analog thermometric precision.

The resistive structure 100 of various embodiments may be used as a basic building block for digital to analog converters (which may also be used in analog to digital converters) while decreasing an area requirement and increasing a power efficiency.

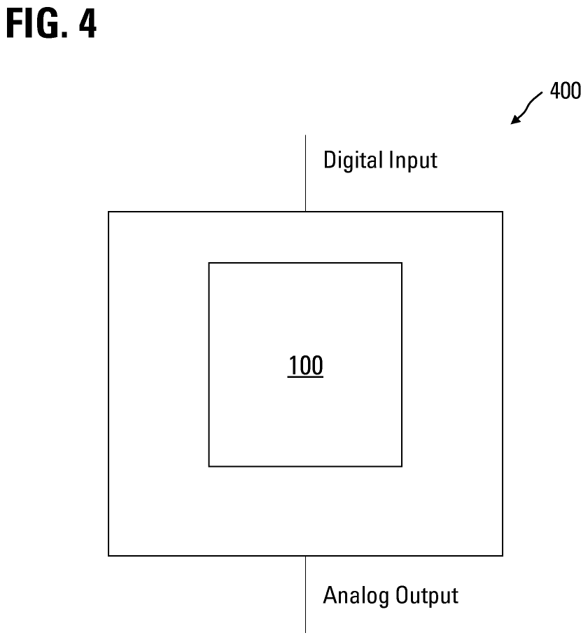

FIG. 4 shows a schematic illustration of a converter 400 in accordance with various embodiments.

The converter 400 may include a resistor structure 100 in accordance with various embodiments, for example as described above, e.g., in context with the figures. The converter 400 may receive a digital input (e.g., SEL<0> to SEL<M> of FIGS. 1 and 2, respectively) and convert it to an analog output (e.g., the output voltage V_{OUT} of FIGS. 1 and 2, respectively).

In a case of even the first switch 104 (e.g., the selector SEL<0> of FIGS. 1 and/or 2, respectively) being de-activated and the input current I_{REF} flowing through first set of resistor elements 102_1 (and through the first switch 104) to ground there, the voltage V_{OUT} may be the product of the input current times the equivalent resistance of the first BL and divided by the activated WLs, in the case all the 102 resistive elements are all programmed to the same resistive value:

$${V}_{OUT} = {I}_{REF} \frac{RRE}{\# ( WL )}$$

This may be representative of a zero-bit-value, e.g., a string of input digital bits <000 . . . 0>.

Various embodiments provide a resistor structure and a method of operating a resistor structure that uses memristive arrays (e.g., RRAMs, PCMs, MRAMs, etc.) to achieve linear voltage sweeps as a function of a digital input.

Using memristive arrays for the embodiments makes it possible to save (semiconductor) area- and power as compared with conventional digital-to-analog converters.

In various embodiments, a circuit architecture of the memristive arrays may be configured to switchably connect bitlines to sourcelines (e.g., bitline to subsequent sourceline or vice versa) by gates. These gates can be digitally switched on/off (thus, using the digital input to drive the switches).

In various embodiments, a wordlines selection may be used for internal calibration of a static gain of an output characteristic.

Thereby, a voltage linearity may be achieved independently of the manufacturing process and temperature variations that could modify resistance values of the resistive elements (the memristors).

The embodiments described above in context with the figures refer to a generic structure of memristive array, but other array architectures may be employed in various embodiments.

In various embodiments, an equivalent resistance that may be generated by applying Kirchhoff laws (both the parallel and series connection of the memristors inside the memory array may be used) may be fully exploited.

Thereby, a dynamic range of the digital-to-analog conversion may be increased, together with a total number of levels (in other words, different equivalent resistance values that may be generated) that can be achieved within this range.

In various embodiments, a dependency of the linearity on the manufacturing process variation and temperature change may be highly reduced, since the equivalent resistance may be tunable by internal calibration.

More specifically, resistor elements 102 connected to a common wordline WL (e.g., a group of resistor elements 102_G1 to 102_GK) may be switched on/off, which may change a slope of the voltage sweep, hence it can be used for simple digital/analog calibration (the control element 102C (the selector) for selecting the wordlines WL may be driven digitally or analogously).

Mutatis mutandis this may be applied also to resistor structures 100 (memristive arrays) that do not use MOS control elements 102C (selectors).

The resistor structure 100 may be programmed in analog/digital way, in order to achieve a multilevel or digital programming.

Advantages of the resistor structure in accordance with various embodiments may include a modularity of the design, a segmented approach for a DAC, and a good performance regarding an Integral Non-Linearity (INL) and a Differential Non-Linearity (DNL).

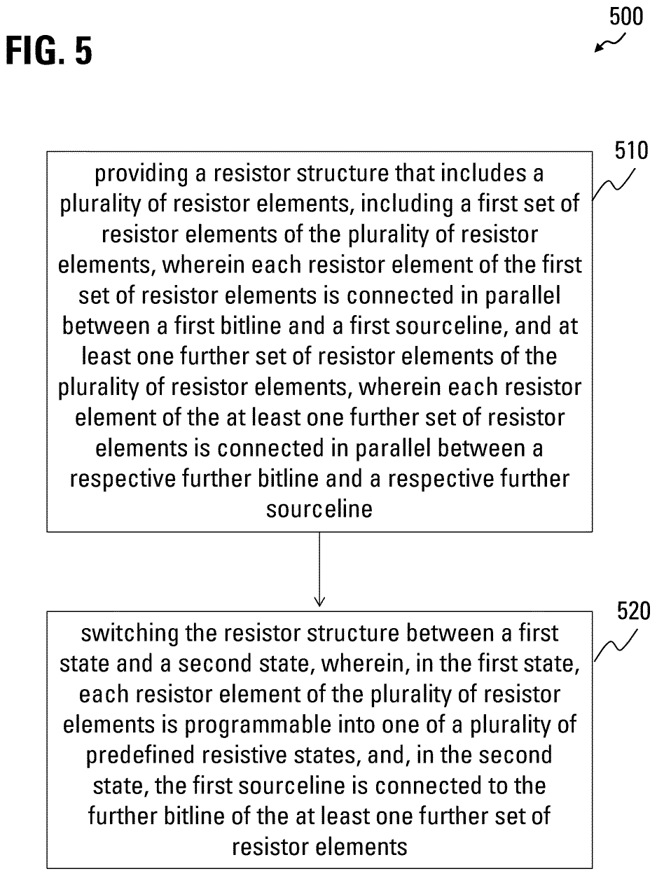

FIG. 5 shows a flow diagram 500 of a method of operating a resistor structure in accordance with various embodiments.

The method includes providing a resistor structure that includes a plurality of resistor elements, including a first set of resistor elements of the plurality of resistor elements, wherein each resistor element of the first set of resistor elements is connected in parallel between a first bitline and a first sourceline, and at least one further set of resistor elements of the plurality of resistor elements, wherein each resistor element of the at least one further set of resistor elements is connected in parallel between a respective further bitline and a respective further sourceline (in 510) and switching the resistor structure between a first state and a second state, wherein, in the first state, each resistor element of the plurality of resistor elements is programmable into one of a plurality of predefined resistive states, and, in the second state, the first sourceline is connected to the further bitline of the at least one further set of resistor elements (in 520).

Various examples will be illustrated in the following:

Example 1 is a resistor structure. The resistor structure includes a plurality of resistor elements, including a first set of resistor elements of the plurality of resistor elements, wherein each resistor element of the first set of resistor elements is connected in parallel between a first bitline and a first sourceline, and at least one further set of resistor elements of the plurality of resistor elements, wherein each resistor element of the at least one further set of resistor elements is connected in parallel between a respective further bitline and a respective further sourceline, and at least one switch configured to switch the resistor structure between a first state and a second state, wherein, in the first state, each resistor element of the plurality of resistor elements is programmable into one of a plurality of predefined resistive states, and, in the second state, the first sourceline is connected to the further bitline of the at least one further set of resistor elements.

In Example 2, the subject-matter of Example 1 may optionally include that, in the second state, the first sourceline is connected in series to the further bitline of the at least one further set of resistor elements, and/or one or more of the respective further sourcelines is connected in series with a subsequent respective further bitline.

In Example 3, the subject-matter of Example 1 or 2 may optionally include that the plurality of resistor elements is additionally organized as a plurality of groups, wherein each group of the plurality of groups includes at least one resistor element from the first set of resistor elements and at least one resistor element each from the further sets of resistor elements, wherein each of the resistor elements includes a resistive structure and a control structure for switching a current through the resistive structure, and wherein the control structures of each group of resistor elements are connected in parallel to a wordline of a plurality of wordlines.

In Example 4, the subject-matter of Example 3 may optionally be configured to define, in the first state, a resistor element of the plurality of resistor elements to be programmed into the predefined resistive state by a combination of activated wordline and activated bitline.

In Example 5, the subject-matter of Example 3 or 4 may optionally be configured to add, in the second state, to an equivalent resistance of the resistor structure, respective resistances of the resistor elements connected to at least one wordline of the plurality of wordlines by activating the at least one wordline, and/or to remove, from the equivalent resistance of the resistor structure, respective resistances of the resistor elements connected to the at least one wordline by deactivating the at least one wordline.

In Example 6, the subject-matter of Example 2 and any of Examples 3 to 5 may optionally include that a last further bitline of the subsequent further bitlines is connected to a last further sourceline of the subsequent further bitlines, and that, in the second state, a voltage VOUT between an input line connected to the first bitline and an output line connected to the last further sourceline is:

$${V}_{OUT} = {I}_{REF} {\sum }_{BL = 0}^{M} \frac{{R}_{RE}}{\# ( WL )} .$$

This formula is valid when all the resistive elements are programmed in the same resistive value. If different resistive values are programmed, this formula is also useful:

$${V}_{OUT} = {I}_{REF} {\sum }_{BL = 0}^{M} {R}_{EQ - BL}$$

wherein IREF is a generic input current of the resistor structure, BL is an index of the M bitlines, RRE is a resistance of the resistive elements, and #(WL) is the total number of activated wordlines.

In Example 7, the subject-matter of any of Examples 1 to 6 may optionally include that, in the first state, each resistor element of the plurality of resistor elements is individually programmable into one of the plurality of predefined resistive states.

In Example 8, the subject-matter of any of Examples 1 to 7 may optionally include that the plurality of resistor elements form an array of resistor elements.

In Example 9, the subject-matter of Example 8 may optionally include that the array of resistor elements includes rows of resistor elements arranged along wordlines and columns of resistor elements arranged along sourcelines and bitlines.

In Example 10, the subject-matter of any of Examples 1 to 9 may optionally include that the first bitline includes a plurality of first bitline branches that are connected in parallel, and/or that the first sourceline includes a plurality of first sourceline branches that are connected in parallel, and/or that the further bitline includes a plurality of further bitline branches that are connected in parallel, and/or that the further sourceline includes a plurality of further sourceline branches that are connected in parallel.

In Example 11, the subject-matter of any of Examples 1 to 10 may optionally include that the resistor elements include or consist of memristive elements.

In Example 12, the subject-matter of any of Examples 1 to 11 may optionally include that the resistor elements are selected from the group consisting of: RRAM, MRAM, PCRAM, and FRAM.

In Example 13, the subject-matter of any of Examples 1 to 12 may optionally include that the at least one switch includes or consists of at least one transistor.

Example 14 is a converter. The converter includes a resistor structure of any of Examples 1 to 13, wherein the converter is a digital-to-analog converter (DAC).

Example 15 is a method of operating a resistor structure. The resistor structure includes a plurality of resistor elements, including a first set of resistor elements of the plurality of resistor elements, wherein each resistor element of the first set of resistor elements is connected in parallel between a first bitline and a first sourceline, and at least one further set of resistor elements of the plurality of resistor elements, wherein each resistor element of the at least one further set of resistor elements is connected in parallel between a respective further bitline and a respective further sourceline. The method includes switching the resistor structure between a first state and a second state, wherein, in the first state, each resistor element of the plurality of resistor elements is programmable into one of a plurality of predefined resistive states, and, in the second state, the first sourceline is connected to the further bitline of the at least one further set of resistor elements.

In Example 16, the subject-matter of Example 15 may optionally include that, in the second state, one or more of the respective further sourcelines is connected in series with a subsequent respective further bitline.

In Example 17, the subject-matter of Example 15 or 16 may optionally include that the plurality of resistor elements is additionally organized as a plurality of groups, wherein each group of the plurality of groups includes at least one resistor element from the first set of resistor elements and at least one resistor element each from the further sets of resistor elements, wherein each of the resistor elements includes a resistive structure and a control structure for switching a current through the resistive structure, and wherein the control structures of each group of resistor elements are connected in parallel to a wordline of a plurality of wordlines.

In Example 18, the subject-matter of Example 17 may optionally include defining, in the first state, a resistor element of the plurality of resistor elements to be programmed into the predefined resistive state by a combination of activated wordline and activated bitline.

In Example 19, the subject-matter of Example 17 or 18 may optionally include adding, in the second state, to an equivalent resistance of the resistor structure, respective resistances of the resistor elements connected to at least one wordline of the plurality of wordlines by activating the at least one wordline, and/or removing, from the equivalent resistance of the resistor structure, respective resistances of the resistor elements connected to the at least one wordline by deactivating the at least one wordline.

In Example 20, the subject-matter of Example 19 may optionally further include adjusting a gain value by activating or deactivating the at least one wordline.

In Example 21, the subject-matter of any of Examples 17 to 20 may optionally include that a last further bitline of the subsequent further bitlines is connected to a last further sourceline of the subsequent further bitlines, wherein, in the second state, a voltage VOUT between an input line connected to the first bitline and an output line connected to the last further sourceline is:

$${V}_{OUT} = {I}_{REF} {\sum }_{BL = 0}^{M} \frac{{R}_{RE}}{\# ( WL )}$$

wherein IREF is a generic input current of the resistor structure, BL is an index of the M bitlines, RRE is a resistance of the resistive elements, and #(WL) is the total number of activated wordlines. If different values are programmed for the resistive elements, the most generic formula to be used is this one:

$${V}_{OUT} = {I}_{REF} {\sum }_{BL = 0}^{M} {R}_{EQ - BL}$$

In Example 22, the subject-matter of any of Examples 15 to 21 may optionally include that, in the first state, each resistor element of the plurality of resistor elements is individually programmable into one of the plurality of predefined resistive states.

In Example 23, the subject-matter of any of Examples 15 to 22 may optionally include that the plurality of resistor elements form an array of resistor elements.

In Example 24, the subject-matter of Example 23 may optionally include that the array of resistor elements includes rows of resistor elements arranged along wordlines and columns of resistor elements arranged along sourcelines and bitlines.

In Example 25, the subject-matter of any of Examples 15 to 24 may optionally include that the first bitline includes a plurality of first bitline branches that are connected in parallel, and/or that the first sourceline includes a plurality of first sourceline branches that are connected in parallel, and/or that the further bitline includes a plurality of further bitline branches that are connected in parallel, and/or that the further sourceline includes a plurality of further sourceline branches that are connected in parallel.

In Example 26, the subject-matter of any of Examples 15 to 25 may optionally include that the at least one switch includes or consists of at least one transistor.

In Example 27, the subject-matter of any of Examples 15 to 26 may optionally include that the resistor elements include or consist of memristive elements.

In Example 28, the subject-matter of any of Examples 15 to 27 may optionally include that the resistor elements are selected from the group consisting of RRAM, MRAM, PCRAM, and FRAM.

Example 29 is a method of operating a converter. The method includes operating the resistor structure of any of Examples 15 to 28 for converting a digital signal to an analog signal.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A resistor structure, comprising:
a plurality of resistor elements, comprising:
a first set of resistor elements of the plurality of resistor elements, wherein each resistor element of the first set of resistor elements is connected in parallel between a first bitline and a first sourceline; and
at least one further set of resistor elements of the plurality of resistor elements, wherein each resistor element of the at least one further set of resistor elements is connected in parallel between a respective further bitline and a respective further sourceline; and
at least one switch configured to switch the resistor structure between a first state and a second state, wherein:
in the first state, each resistor element of the plurality of resistor elements is programmable into one of a plurality of predefined resistive states; and
in the second state, the first sourceline is connected to the respective further bitline of the at least one further set of resistor elements.

2. The resistor structure of claim 1, wherein, in the second state, the respective further sourceline is connected to a subsequent respective further bitline.

3. The resistor structure of claim 1, wherein:
the plurality of resistor elements is further organized as a plurality of groups;
each group of the plurality of groups comprises at least one resistor element from the first set of resistor elements and at least one resistor element each from the at least one further set of resistor elements;
each resistor element of the plurality of resistor elements comprises a resistive structure and a control structure for switching a current through the resistive structure; and
the control structure of each resistor element of each group of resistor elements is connected in parallel to a wordline of a plurality of wordlines.

4. The resistor structure of claim 3, wherein the resistor structure is configured to define, in the first state, a resistor element of the plurality of resistor elements to be programmed into one of the plurality of predefined resistive states by a combination of activated wordline and activated bitline.

5. The resistor structure of claim 3, wherein the resistor structure is configured to:
add, in the second state, to an equivalent resistance of the resistor structure, respective resistances of resistor elements of the plurality of resistor elements connected to at least one wordline of the plurality of wordlines by activating the at least one wordline; or
remove, from the equivalent resistance of the resistor structure, respective resistances of resistor elements of the plurality of resistor elements connected to the at least one wordline by deactivating the at least one wordline.

6. The resistor structure of claim 3, wherein:
in the second state, the respective further sourceline of a plurality of further sourcelines is connected to a subsequent respective further bitline of a plurality of subsequent further bitlines;
a last further bitline of the plurality of subsequent further bitlines is connected to a last further sourceline of the plurality of further sourcelines; and
in the second state, a voltage V_{OUT} between an input line connected to the first bitline and an output line connected to the last further sourceline is:
$${V}_{OUT} = {I}_{REF} {\sum }_{BL = 0}^{M} \frac{{R}_{RE}}{\# ( WL )}$$
where I_{REF} is a generic input current of the resistor structure, BL is an index of the M bitlines, R_{RE} is a resistance of the resistive elements, and #(WL) is the total number of activated wordlines.

7. The resistor structure of claim 1, wherein, in the first state, each resistor element of the plurality of resistor elements is individually programmable into one of the plurality of predefined resistive states.

8. The resistor structure of claim 1, wherein the plurality of resistor elements form an array of resistor elements.

9. The resistor structure of claim 8, wherein the array of resistor elements comprises rows of resistor elements arranged along wordlines and columns of resistor elements arranged along sourcelines and bitlines.

10. The resistor structure of claim 1, wherein:
the first bitline comprises a plurality of first bitline branches that are connected in parallel; or
the first sourceline comprises a plurality of first sourceline branches that are connected in parallel; or
the further bitline comprises a plurality of further bitline branches that are connected in parallel; or
wherein the further sourceline comprises a plurality of further sourceline branches that are connected in parallel.

11. The resistor structure of claim 1, wherein the resistor elements comprise or consist of memristive elements.

12. The resistor structure of claim 1, wherein the resistor elements are selected from the group consisting of:
resistive random-access memory (RRAM);
magnetoresistive random-access memory (MRAM);
phase change random-access memory (PCRAM); and
ferroelectric random-access memory (FRAM).

13. A converter comprising the resistor structure of claim 1, wherein the converter is a digital-to-analog converter.

14. A method of operating a resistor structure comprising a plurality of resistor elements, the plurality of resistor elements comprising: a first set of resistor elements of the plurality of resistor elements, wherein each resistor element of the first set of resistor elements is connected in parallel between a first bitline and a first sourceline; and at least one further set of resistor elements of the plurality of resistor elements, wherein each resistor element of the at least one further set of resistor elements is connected in parallel between a respective further bitline and a respective further sourceline, the method comprising:
switching the resistor structure between a first state and a second state, wherein:
in the first state, each resistor element of the plurality of resistor elements is programmable into one of a plurality of predefined resistive states; and
in the second state, the first sourceline is connected to the further bitline of the at least one further set of resistor elements.

15. The method of claim 14, wherein, in the second state, one or more of the respective further sourcelines is connected in series with a subsequent respective further bitline.

16. The method of claim 14, wherein:
the plurality of resistor elements is further organized as a plurality of groups;
each group of the plurality of groups comprises at least one resistor element from the first set of resistor elements and at least one resistor element each from the at least one further set of resistor elements;
each of the resistor elements comprises a resistive structure and a control structure for switching a current through the resistive structure; and
the control structures of each group of resistor elements are connected in parallel to a wordline of a plurality of wordlines.

17. The method of claim 16, further comprising:
adding, in the second state, to an equivalent resistance of the resistor structure, respective resistances of the resistor elements connected to at least one wordline of the plurality of wordlines by activating the at least one wordline; or
removing, from the equivalent resistance of the resistor structure, respective resistances of the resistor elements connected to the at least one wordline by deactivating the at least one wordline.

18. The method of claim 17, further comprising:
adjusting a gain value by activating or deactivating the at least one wordline.

19. A method, comprising:
converting a digital signal to an analog signal by operating a resistor structure comprising a plurality of resistor elements, the plurality of resistor elements comprising:
a first set of resistor elements of the plurality of resistor elements, wherein each resistor element of the first set of resistor elements is connected in parallel between a first bitline and a first sourceline, and
at least one further set of resistor elements of the plurality of resistor elements, wherein each resistor element of the at least one further set of resistor elements is connected in parallel between a respective further bitline and a respective further sourceline.
